(19) United States
(12) Patent Application Publication
(10) Pub. No.: US 2010/0285630 A1
(43) Pub. Date: Nov. 11, 2010

(54) Method of manufacturing an image sensor having improved anti-reflective layer

(75) Inventor: Yun-Ki Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/662,861

(22) Filed: May 7, 2010

(30) Foreign Application Priority Data
May 7, 2009 (KR) 10-2009-0039733

(51) Int. Cl. H01L 31/18; H01L 21/30

(52) U.S. Cl. 438/70; 438/72; 257/E21.211; 257/E31.127; 257/E31.119

(57) ABSTRACT

In a method of manufacturing an image sensor, a photodiode may be formed in a light receiving region of a substrate having a first surface. A conductive wiring may be formed on the first surface of the substrate. After removing a portion of the substrate opposite to the first surface, an anti-reflective layer may be formed on a second surface of the substrate. The second surface may be opposite to the first surface. The anti-reflective layer and the light receiving region may be thermally treated to cure defects including dangling bonds in the substrate and to improve a refraction index of the anti-reflective layer. The image sensor may have an enhanced light transmittance and may produce high-definition images.

### CROSS-REFERENCE TO RELATED APPLICATION

This application claims priority under 35 U.S.C. §119 to Korean patent Application No. 2009-39733, filed on May 7, 2009, in the Korean Intellectual Property Office (KIPO), the disclosure of which is hereby incorporated by reference herein in its entirety.

### BACKGROUND

1. Field

Example embodiments of the inventive concept relate to image sensors and methods of manufacturing image sensors. More particularly, example embodiments of the inventive concept relate to complementary metal oxide semiconductor (CMOS) image sensors having improved anti-reflective layer, and methods of manufacturing the same.

2. Description

An image sensor converts an optical signal into an electrical signal. The image sensor may include a photoelectric transforming element that detects light and a logic circuit element that transforms the detected light into the electrical signal including data. The image sensor may further include micro lenses that focus/concentrate the light in the direction of the photoelectric transforming element to improve the sensitivity of the light. The image sensor is used in various electric and electronic apparatuses such as a digital camera, a video camera, a cellular phone, a personal communication system (PSC), a video game console, a closed-circuit television, a medical micro camera, or the like. It may, therefore, be beneficial for the image sensor to have superior electrical characteristics and performance.

In a conventional image sensor, a plurality of wirings are formed on a substrate having a photoelectric transforming element, and then a color filter and micro lenses are disposed over the wirings. The conventional image sensor may not ensure a proper focal distance because of an increased distance between the photoelectric transforming element and the color filter. Further, the light receiving efficiency of the photoelectric transforming element may be reduced since the wirings diffuse or block light incident on the conventional image sensor.

In a conventional back side illumination type image sensor, a color filter and micro lenses are formed on a rear face of a substrate and a photoelectric transforming element and wirings are formed on a front face of the substrate. Thus, a distance between the color filter and the photoelectric transforming element may be reduced and light may be correctly irradiated on the photoelectric transforming element. However, the conventional back side illumination type image sensor may have poor quality of displayed pictures. This is because noise and/or dark current may be present in the image sensor and this may reduce charge transferring efficiency and charge storage capacity of the image sensor.

In the conventional back side illumination type image sensor, the dark current may be generated by the accumulation of the charges that are created in the absence of incident light. This dark current may be caused due to dangling bonds such as bonds of silicon and oxygen (—Si—O—) or bonds between silicon (—Si—Si—). When a surface of a substrate has dangling bonds, thermal charges may be easily generated in the image sensor including such a substrate even though light is not irradiated onto the image sensor. Hence, the image sensor may have a deteriorated pictures quality as a result of the dark current.

During manufacture of the conventional back side illumination type image sensor, an anti-reflective layer is usually formed on a light receiving region of a semiconductor substrate after partially removing a rear portion of the semiconductor substrate by a thinning process. However, light incident on the image sensor may suffer diffraction due to lattice defects of the anti-reflective layer and the substrate, for example lattice parameter mismatch, due to which the image sensor may have poor light transmittance. Further, the anti-reflective layer of the conventional image sensor may not have a desired dense structure since the anti-reflective layer is not thermally treated at a correct high temperature after elements of the image sensor are formed on the semiconductor substrate, thereby deteriorating the light transmittance of the image sensor further.

### SUMMARY

According to example embodiments, a method of manufacturing an image sensor, includes forming a photodiode on a light receiving region of a substrate having a first surface; forming a conductive wiring on the first surface of the substrate; removing a portion of the substrate opposite to the first surface; forming an anti-reflective layer on a second surface of the substrate, the second surface being opposite to the first surface; and thermally treating the anti-reflective layer and the light receiving region of the substrate.

According to example embodiments, thermally treating the anti-reflective layer and the light receiving region of the substrate may include a laser annealing process, a flash lamp annealing process or an ultraviolet ray annealing process.

According to example embodiments, thermally treating the anti-reflective layer and the light receiving region of the substrate may cure defects in the light receiving region and may increase a refraction index of the anti-reflective layer.

According to example embodiments, thermally treating the anti-reflective layer and the light receiving region of the substrate may be performed using a laser beam having energy substantially smaller than a band gap energy of silicon.

According to example embodiments, the laser beam may have a wavelength substantially greater than about 1.2 μm.

According to example embodiments, thermally treating the anti-reflective layer and the light receiving region of the substrate may be performed at a temperature of about 500° C. to about 1,000° C.

According to example embodiments, the anti-reflective layer may include a silicon compound or a metal compound.

According to example embodiments, the anti-reflective layer may include silicon nitride, silicon oxynitride, titanium oxide, tantalum oxide, hafnium oxide, zirconium oxide or a combination thereof.

According to example embodiments, the anti-reflective layer may have a refraction index of about 1.5 to about 3.0.

According to example embodiments, the method of manufacture may further include decreasing a difference in refraction index between the anti-reflective layer and the substrate by thermally treating the anti-reflective layer and the light receiving region of the substrate.

According to example embodiments, the method may further include forming an epitaxial layer on the substrate before forming the photodiode, and removing the portion of the substrate till the epitaxial layer is exposed.

According to example embodiments, forming the photodiode may include doping first impurities in a portion of the epitaxial layer and doping second impurities on the first impurities.

According to example embodiments, the method may further include forming at least one gate structure on the first surface of the substrate; forming at least one insulation layer covering the at least one gate structure; and electrically connecting the conductive wiring to the at least one gate structure through the at least one insulation layer.

According to example embodiments, the method may further include forming a color filter layer on the anti-reflective layer; and forming a micro lens on the color filter layer.

According to example embodiments, an image sensor includes a substrate having a first surface and a second surface opposite to the first surface; a photodiode in a light receiving region of the substrate; a conductive wiring on the first surface of the substrate; an anti-reflective layer on the second surface of the substrate; a color filter layer on the anti-reflective layer; and a micro lens on the color filter layer, wherein the anti-reflective layer and the light receiving region are thermally treated.

According to example embodiments, the image sensor may further include an epitaxial layer on the substrate, wherein the photodiode may be located in the epitaxial layer.

According to example embodiments, thermally treating the anti-reflective layer and the light receiving region may cure defects of the epitaxial layer and may increase a refraction index of the anti-reflective layer.

According to example embodiments, the anti-reflective layer and the light receiving region may be thermally treated by a laser annealing process, a flash lamp annealing process or an ultraviolet ray annealing process.

According to example embodiments, the anti-reflective layer may include a silicon compound or a metal compound.

According to example embodiments, the image sensor may further include at least one gate structure on the first surface of the substrate; and at least one insulation layer covering the at least one gate structure, wherein the conductive wiring is electrically connected to the at least one gate structure through the at least one insulation layer.

### BRIEF DESCRIPTION OF THE DRAWINGS

The above and other features and advantages will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a plan view illustrating an image sensor according to example embodiments;

FIG. 2 is a circuit diagram illustrating a unit pixel of a CMOS image sensor according to example embodiments;

FIG. 3 is a cross sectional view illustrating an image sensor according to example embodiments;

FIG. 4 is a graph illustrating a refractive index variation of an anti-reflective layer relative to a temperature according to example embodiments;

FIG. 5 is a graph illustrating a light transmittance variation of an anti-reflective layer relative to a wavelength according to example embodiments;

FIGS. 6 to 15 are cross sectional views illustrating a method of manufacturing an image sensor according to example embodiments;

FIG. 16 is a block diagram illustrating an electronic system including an image sensor according to example embodiments; and

FIG. 17 is a block diagram representation of an image sensor chip included in an electronic system according to example embodiments.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

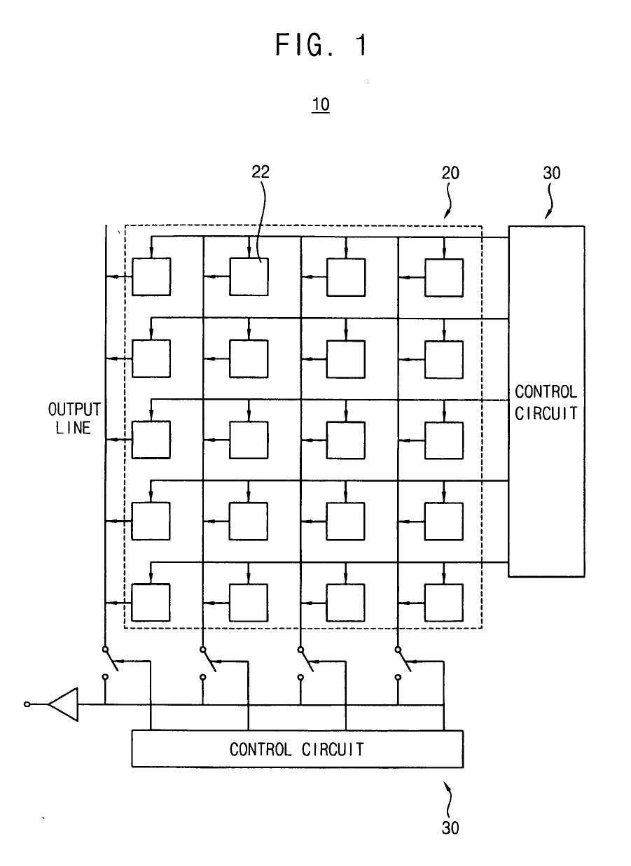

FIG. 1 is a plan view illustrating an image sensor according to example embodiments. Although a CMOS image sensor is illustrated in FIG. 1, the features of example embodiments may be employed in other image sensors as well.

Referring to FIG. 1, the CMOS image sensor includes a light receiving area 20 and a peripheral area 30. Active pixel arrays may be disposed in the light receiving area 20. In the light receiving area 20, a plurality of unit pixels 22 may be arranged in a matrix structure.

CMOS control circuits may be disposed in the peripheral area 30. Each of the CMOS control circuits may include a plurality of CMOS transistors. The CMOS control circuits may provide control signals to the unit pixels 22 in the light receiving area 20. Further, the CMOS control circuits may adjust photoelectric transformation signals generated from the unit pixels 22 in the light receiving area 20.

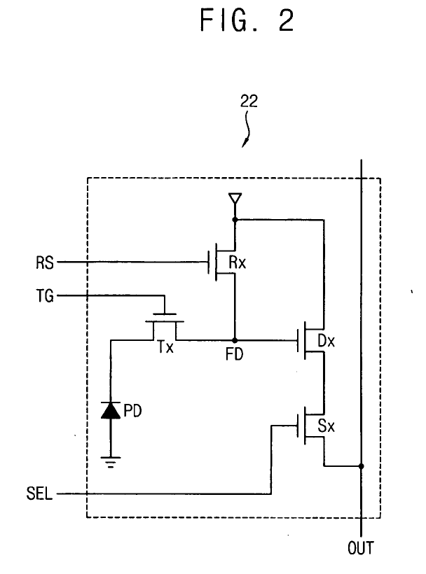

FIG. 2 is an equivalent circuit diagram illustrating a unit pixel of a CMOS image sensor according to example embodiments.

Referring to FIGS. 1 and 2, the unit pixel 22 of the CMOS image sensor may include a photodiode (PD), a transfer transistor (Tx), a reset transistor (Rx), a drive transistor (Dx), and a select transistor (Sx). The photodiode (PD) may receive external light and may generate photo charges, and the transfer transistor (Tx) may transfer the generated photo charges to a floating diffusion region (FD). The reset transistor (Rx) may periodically reset the photo charges stored in the floating diffusion region (FD). The drive transistor (Dx) may serve as a source follower buffer amplifier and may buffer signals in accordance with the photo charges stored in the floating diffusion region (FD). The select transistor (Sx) may serve as a switching element for selecting the unit pixel 22.

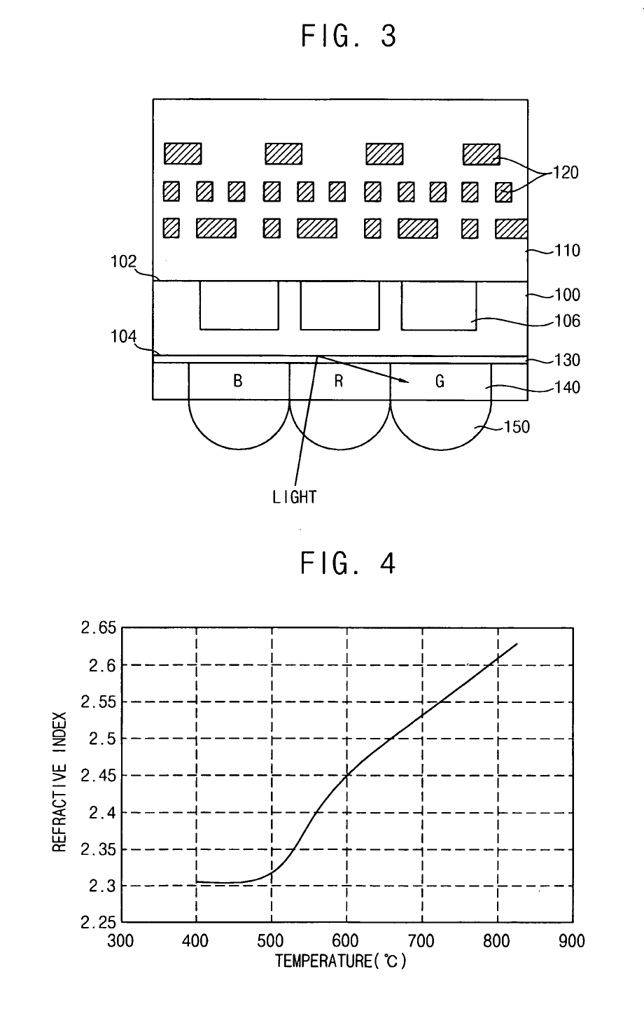

FIG. 3 is a cross sectional view illustrating an image sensor according to example embodiments. Although a CMOS image sensor illustrated in FIG. 3 may be of a back side illumination type, the CMOS image sensor may also be a front side illumination type based on positions of elements in the image sensor.

Referring to FIG. 3, the image sensor includes a substrate 100, a plurality of photodiodes 106, an insulation layer 110, conductive wirings 120 and an anti-reflective layer 130.

The substrate 100 may have a first surface 102 and a second surface 104. For example, the first surface 102 and the second surface 104 may respectively correspond to a front face and a rear face of the substrate 100. The substrate 100 may include a semiconductor substrate, for example, a silicon substrate, a germanium substrate, a silicon-germanium substrate, or the like. Alternatively, the substrate 100 may include a substrate having a semiconductor layer such as a silicon-on-insulator (SOI) substrate, a germanium-on-insulator (GOI) substrate, or the like.

The photodiodes 106 are disposed on the first surface 102 of the substrate 100. The photodiodes 106 may be regularly arranged on the first surface 102 of the substrate 100. In example embodiments, the photodiodes 106 may be buried in the substrate 100.

The insulation layer 110 is formed on the first surface 102 of the substrate 100 and may cover the photodiodes 106. In example embodiments, the insulation layer 110 may have a multi layer structure that includes a plurality of insulation films. For example, the insulation films may include oxide such as silicon oxide. The conductive wirings 120 are in the insulation layer 110. Each of the conductive wirings 120 may include a conductive material, for example, metal and/or metal compound.

The anti-reflective layer 130 is on the second surface 104 of the substrate 100. The anti-reflective layer 130 may include a silicon compound and/or a metal compound. The image sensor may further include a color filter layer 140 on the anti-reflective layer 130. In example embodiments, the color filter layer 140 may include have a plurality of color filter arrays including a red (R) filter, a green (G) filter, a blue (B) filter, etc.

The image sensor may additionally include micro lenses 150 on the color filter layer 140. Light passing through the micro lenses 150 may be filtered by the color filter layer 140, and then the light may be converted into photo charges by the photodiodes 106.

According to example embodiments, light incident on the micro lenses 150 may partially pass through the micro lenses 150 and may partially be reflected from the micro lenses 150. The reflected light may also be incident on other unit pixels adjacent to the unit pixel on which the light is incident. To prevent the reflected light from affecting the adjacent unit pixels, the anti-reflective layer 130 is provided on the second surface 104 of the substrate 100.

When the anti-reflective layer 130 has a refractive index substantially smaller than that of the substrate 100, the light incident on the second surface 104 of the substrate 100 may be reflected from the second surface 104 of the substrate 100 because of the refractive index difference between the anti-reflective layer 130 and the substrate 100. When the refractive index of the anti-reflective layer 130 is substantially equal to that of the substrate 100, the light incident on the second surface 104 of the substrate 100 may pass through the second surface 104 of the substrate 100 since the transmittance of the light relative to the second surface 104 may increase. Thus, the amount of the light reflected from the second surface 104 of the substrate 100 may be considerably reduced.

In a conventional manufacturing method, the conductive wirings 120 may be formed in the insulation layer 110 on the first surface 102 of the substrate 100 before forming the anti-reflective layer 130 on the second surface 104 of the substrate 100. Hence, the substrate 100 having the conductive wiring 120 and the anti-reflective layer 130 may not be thermally treated at a relative high temperature, for example, above about 400° C. That is, the anti-reflective layer 130 on the second surface 104 of the substrate 100 may be well treated to improve the reflectivity of the light incident thereon. Therefore, defects that cause a dark current such as dangling bonds in the substrate 100 may not be sufficiently cured to deteriorate electrical characteristics of the image sensor. Further, the anti-reflective layer 130 may not be of a desired dense structure to reduce the transmittance of the light irradiated thereon. When the image sensor is of the conventional back side illumination type, the image sensor may have light receiving structures formed on the substrate 100 after partially removing the substrate by a thinning process. As a result, the conventional back side illumination type image sensor may have deteriorated characteristics because the defects causing the dark current may not be sufficiently cured, although the dangling bonds may be frequently generated in the substrate 100.

In example embodiments, the anti-reflective layer 130 may include a silicon compound and/or a metal compound that may have a refraction index in a range of about 1.5 to about 3.0. For example, the anti-reflective layer 130 may include silicon nitride (SiNx), silicon oxynitride (SiOxNy), titanium oxide (TiOx), hafnium oxide (HfOx), tantalum oxide (TaOx), zirconium oxide (ZrOx), and/or a mixture thereof.

Silicon usually has a refraction index below about 3.4, so that the anti-reflective layer 130 including the silicon compound may have an increased refraction index to reduce the refraction index difference between the anti-reflective layer 130 and the substrate 100.

FIG. 4 is a graph illustrating a refractive index variation of an anti-reflective layer relative to temperature according to example embodiments.

As illustrated in FIG. 4, when the anti-reflective layer including silicon nitride is treated at a temperature of about 400° C., the anti-reflective layer may have a refraction index of about 2.3 relative to light having a wavelength of about 500 nm. The refraction index of the anti-reflective layer may slightly increase at a temperature of about 500° C., and the refraction index of the anti-reflective layer may rapidly increase when the temperature is between about 500° C. and about 600° C. Further, the refraction index of the anti-reflective layer may gradually increase when the temperature is above about 600° C.

According to example embodiments, the substrate 100 having the anti-reflective layer 130 may be thermally treated to improve the refraction index of the anti-reflective layer 130 and to crystallize the anti-reflective layer 130. For example, the anti-reflective layer 130 may be treated by a rapid thermal process including a laser annealing process. In the laser annealing process for the anti-reflective layer 130, a laser beam may be irradiated onto the anti-reflective layer 130 using a plurality of filtering lenses and a polarization system. A desired portion of an object or a thin film may be thermally treated by the laser annealing process. Thus, desired portions of the anti-reflective layer 130 may be thermally treated by the laser annealing process. Since a laser beam having a desired wavelength may be selectively absorbed by a specific material, the structure and/or the property of the anti-reflective layer 130 may be changed by irradiating a laser beam onto the anti-reflective layer 130.

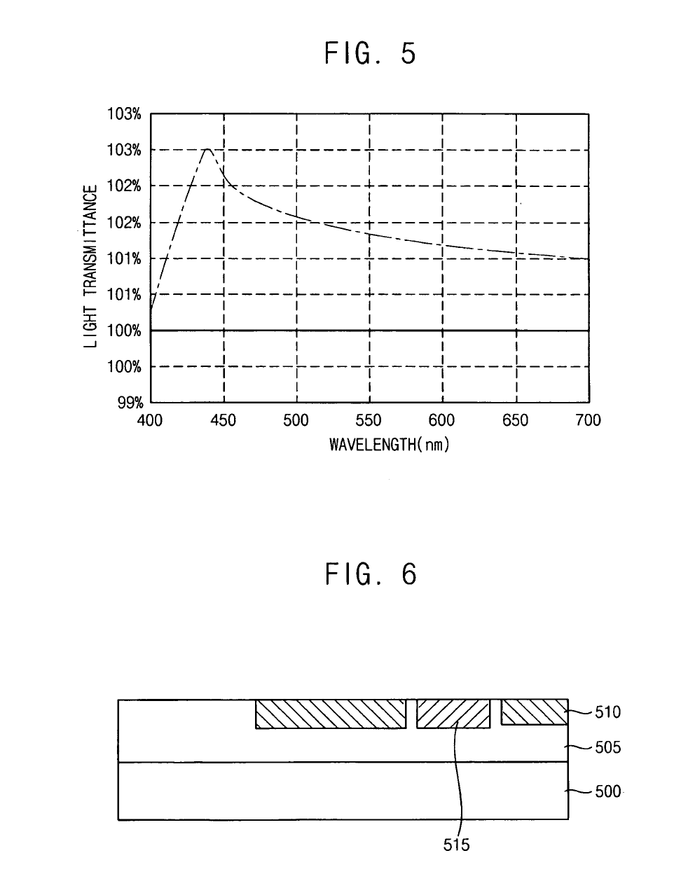

FIG. 5 is a graph illustrating a light transmittance variation of an anti-reflective layer relative to a wavelength according to example embodiments. In FIG. 5, a horizontal axis indicates a wavelength of a light incident on an anti-reflective layer and a vertical axis represents a light transmittance relative to a light transmittance of a first anti-reflective layer, which is not thermally treated, considered at 100%. The relative light transmittance of a second thermally treated anti-reflective layer is denoted as a dashed line whereas light transmittance of a first anti-reflective layer is indicated as a bold line. The second anti-reflective layer is formed using silicon nitride and is thermally treated at a temperature of about 800° C.

As illustrated in FIG. 5, the second anti-reflective layer has an improved light transmittance larger than that of the first anti-reflective layer by about 1.0% to about 3.0% in accordance with the wavelength of the incident light. When an anti-reflective layer is formed by an atomic layer deposition (ALD) process or a chemical vapor deposition (CVD) process, a lattice structure of the anti-reflective layer may not be dense and the anti-reflective layer may have an amorphous structure because the anti-reflective layer is obtained at a relatively low temperature of about 400° C. to about 500° C.

According to example embodiments, the anti-reflective layer may be thermally treated by a laser annealing process at a relatively high temperature of about 500° C. to about 1,000° C. without melting the substrate, so that the anti-reflective layer may be made dense and the lattice structure of the anti-reflective layer may be changed into a crystalline state from an amorphous state. Hence, the anti-reflective layer may exhibit an increased refraction index. When the anti-reflective layer has an increased refraction index, a difference of a refraction index between the anti-reflective layer and the substrate may also be decreased, thereby improve a light transmittance of the image sensor. In the laser annealing process, defects caused by lattice parameter mismatch in the substrate may be cured and also dangling bonds in the substrate may be removed, so that generation of dark current in the image sensor may be prevented. Therefore, the image sensor may provide better images while improving the transmittance of the image sensor. Further, adhesion strength between the anti-reflective layer and the substrate may be improved by the laser annealing process.

FIGS. 6 to 15 are cross sectional views illustrating a method of manufacturing an image sensor according to example embodiments. The method illustrated in FIGS. 6 to 15 may be used to manufacture a CMOS image sensor, for example.

Referring to FIG. 6, an epitaxial layer 505 is formed on a substrate 500. The substrate 500 may include a semiconductor substrate or a substrate having a semiconductor layer. For example, the substrate 500 may include a silicon substrate, a germanium substrate, a silicon-germanium substrate, an SOI substrate, a GOI substrate, etc.

The epitaxial layer 505 may have a first conductivity. The epitaxial layer 505 may be formed on the substrate 500 by an epitaxial growth process using the substrate 500 as a seed. A plurality of elements such as wells and/or conductive regions of the image sensor may also be provided in the epitaxial layer 505 when the image sensor includes the CMOS image sensor. The epitaxial layer 505 may have a thickness of about 5.0 μm to about 15.0 μm measured from an upper surface of the substrate 500.

A first well 510 and a second well 515 are formed in the epitaxial layer 505. The first well 510 may have a second conductivity and the second well 515 may have a third conductivity. For example, the first well 510 may have an electrical conductivity different from the first conductivity of the epitaxial layer 505 whereas the second well 515 may have an electrical conductivity substantially the same as the first conductivity of the epitaxial layer 505. Each of the first and the second wells 510 and 515 may be formed by an ion implantation process, for example. Namely, first and second impurities may be doped into desired portions of the epitaxial layer 505 to form the first and the second wells 510 and 515, respectively. Here, the first impurity may be different from the second impurity.

In example embodiments, the first well 510 may have a depth substantially the same as that of the second well 515. Alternatively, the first and the second wells 510 and 515 may have different depths according to the electrical characteristics of the image sensor.

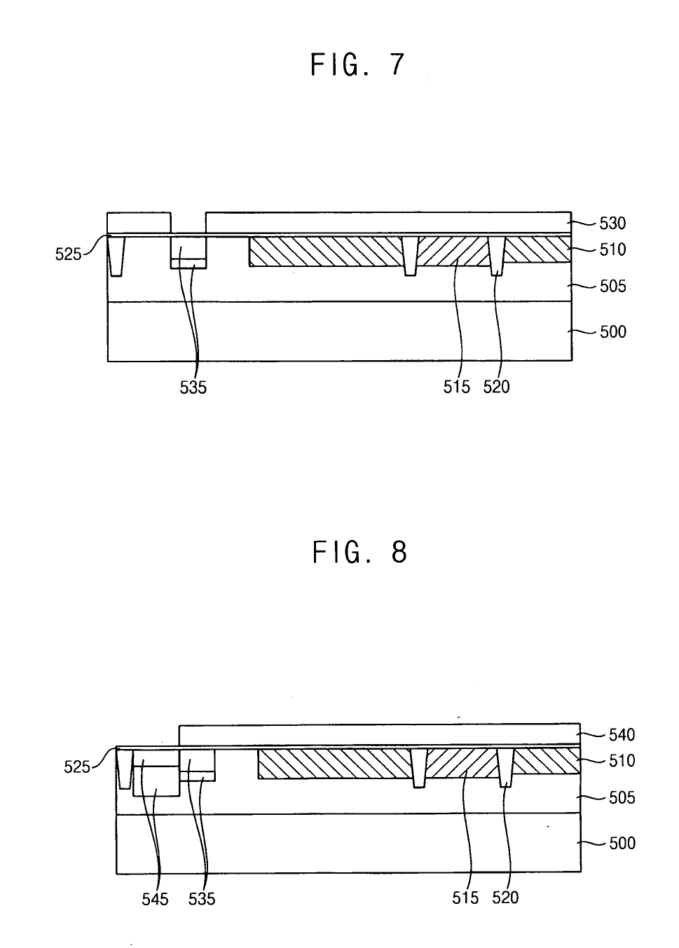

Referring to FIG. 7, isolation layers 520 are formed on the substrate 500 having the epitaxial layer 505. The isolation layers 520 are positioned adjacent to portions of the epitaxial layer 520 where photodiodes 545 (see FIG. 8) will be formed. Further, the isolation layers 520 are located at portions of the epitaxial layer 520 between the first well 510 and the second well 515. The isolation layers 520 may be formed by an isolation process such as a shallow trench isolation (STI) process. Each of the isolation layers 520 may be formed using an oxide. For example, the isolation layers 520 may include undoped silicate glass (USG), spin on glass (SOG), flowable oxide (FOX), tetraethyl ortho silicate (TEOS), plasma enhanced-tetraethyl ortho silicate (PE-TEOS), Tonen Silazane (TOSZ®), high density plasma-chemical vapor deposition (HDP-CVD) oxide, or the like.

In example embodiments, the isolation layers 520 may include first isolation layers and second isolation layers. The first isolation layers may electrically insulate adjacent photodiodes 545 and the second isolation layers may electrically insulate adjacent switching devices such as transistors. Each of the first isolation layers may have a depth and/or a width substantially different from a depth and/or a width of each second isolation layer.

In the image sensor according to example embodiments, each of the photodiodes 545 may have a depth greater than about 2.0 μm since a red light from the light incident on the image sensor may have a relatively large wavelength of about 0.4 μm to about 0.5 μm. Even though an image sensor may include an isolation layer having a relatively thin depth below about 2.0 μm, elements in the image sensor may be electrically insulated from one another by the relatively thin isolation layer. However, a cross-talk may occur between adjacent pixels of the image sensor when the isolation layer for electrically insulating adjacent photodiodes has the relative thin thickness less than about 2.0 μm. Although the isolation layers in the image sensor may have the same thickness above about 2.0 μm, the depths of the isolation layers may increase according as the thicknesses of the isolation layers increase, so that the image sensor may have a lowered integration degree/density. According to example embodiments, the first isolation layers for electrically insulating adjacent photodiodes 545 may have depths and/or widths substantially larger than depths and/or widths of the second isolation layer for electrically insulating adjacent switching devices.

In example embodiments, the isolation layers 520 positioned in a light receiving area of the image sensor may be adjacent to the substrate 500 or may contact with the substrate 500. Impurity regions may be additionally formed in the isolation layers 520 or may be formed in the epitaxial layer 505. The isolation layers 520 and the impurity regions may prevent the color mixing phenomenon. When the isolation layers 520 and the impurity regions enclose the photodiodes 545, the light irradiated through a rear face of the substrate 500 may not be refracted between adjacent photodiodes 545. Therefore, the color mixing phenomenon between adjacent photodiodes 545 may be efficiently prevented by the isolation layers 520 and the impurity regions.

Referring now to FIG. 7, a gate insulation layer 525 is formed on the epitaxial layer 505 and the isolation layers 520. The gate insulation layer 525 may cover the first and the second wells 510 and 515. The gate insulation layer 525 may be formed using oxide and/or metal oxide. For example, the gate insulation layer 525 may include silicon oxide, hafnium oxide (HfOx), zirconium oxide (ZrOx), titanium oxide (TiOx), aluminum oxide (AlOx), tantalum oxide (TaOx) or a mixture thereof. The gate insulation layer 525 may be formed by a chemical vapor deposition (CVD) process, a sputtering process, an atomic layer deposition (ALD) process, an evaporation process, or the like.

After forming a first photoresist pattern 530 on the gate insulation layer 525, a transfer channel region 535 is formed in a portion of the epitaxial layer 505 where a transfer transistor will be formed. The transfer channel region 535 may include a first channel region and a second channel region. The first and the second channel regions of the transfer channel region 535 may have different conductivity types, respectively. For example, the first channel region may have a conductivity type substantially the same as that of the epitaxial layer 505 whereas the second channel region may have a conductivity type opposite to that of the epitaxial layer 505.

The first photoresist pattern 530 is removed from the gate insulation layer 520 after forming the transfer channel region 535. For example, the first photoresist pattern 530 may be removed by a stripping process and/or an ashing process.

Referring to FIG. 8, a second photoresist pattern 540 is formed on the gate insulation layer 520. The second photoresist pattern 540 exposes the portions of the epitaxial layer 505 where the photodiodes 545 are formed. Impurities may be doped in the portions of the epitaxial layer 505 to form the photodiodes 545 adjacent to the transfer channel region 535. Here, the second photoresist pattern 540 may serve as an implantation mask for forming the photodiodes 545.

In example embodiments, the photodiodes 545 are formed in the epitaxial layer 505 by implanting impurities into the epitaxial layer 505. For example, third impurities having a fourth (second) conductivity may be doped in the epitaxial layer 505, and fourth impurities having a fifth conductivity may be implanted in the third impurities to form the photodiodes 545 having substantially vertical structures. The fourth conductivity of the third impurities may be substantially different from that of the epitaxial layer 505 whereas the fifth conductivity of the fourth impurities may be substantially the same as that of the epitaxial layer 505. When the photodiode 545 includes the third and the fourth impurities, depletion regions may be generated between the photodiode 545 and the epitaxial layer 505 so that the image sensor having the photodiodes 545 may be correctly operated.

When the photodiodes 545 have depths substantially larger than the relatively large wavelength of the red light, the photodiodes 545 may receive almost all of the light irradiated on the photodiodes 545. Thus, the image sensor may ensure an improved light sensitivity and enhanced quality of pictures. According to example embodiments, each of the photodiodes 545 may have a depth of about 5.0 μm measured from an upper surface of the epitaxial layer 505 by controlling energies of ion during the implantation processes for forming the photodiodes 545. Here, the depletion region may be formed at a portion of the epitaxial layer 505 beneath the photodiode 545. When the depletion region has a relatively large width, the electrical cross-talk of the image sensor may decrease. That is, the image sensor may have enhanced electrical characteristics by controlling the impurity concentration of the epitaxial layer 505 and the dimensions of the photodiodes 545.

After forming the photodiodes 545 on the substrate 500, the second photoresist pattern 540 may be removed from the gate insulation layer 525. For example, the second photoresist pattern 540 may be removed by a stripping process and/or an ashing process.

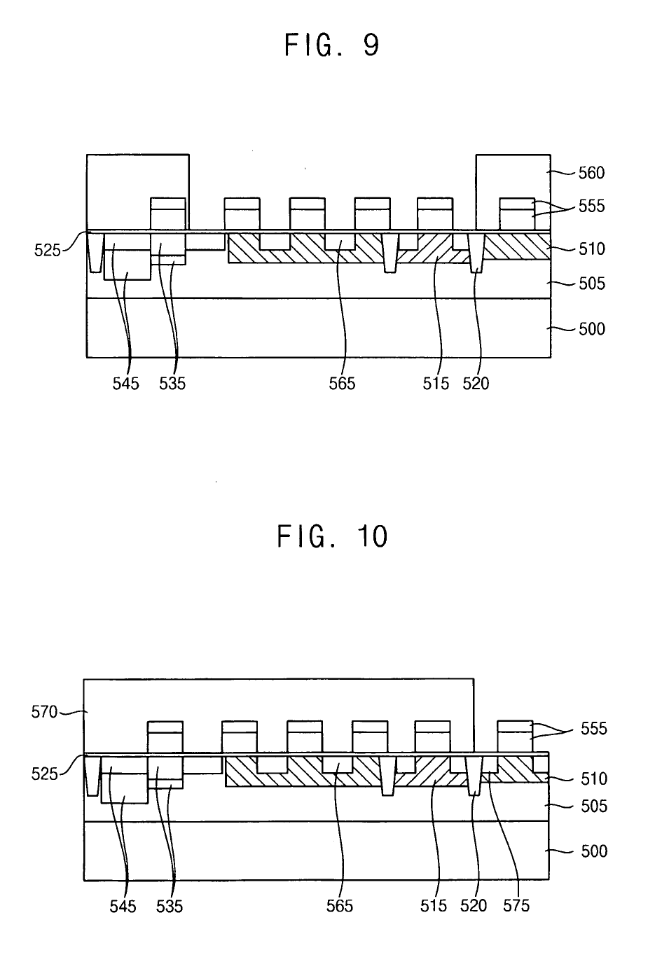

Referring to FIG. 9, gate structures 555 are formed on the gate insulation layer 525 and the photodiodes 545. When the substrate 500 has an active pixel sensor (APS) array area and a peripheral circuit area, a plurality of gate structures 555 may be formed in the APS and the peripheral circuit area of the substrate 500. Each of the gate structures 555 may have a multi layer structure that includes a gate electrode, a gate mask, or the like. The gate electrodes of the gate structures 555 may be formed using polysilicon, metal and/or metal compound. For example, the gate electrodes may include polysilicon doped with impurities, tungsten, tungsten nitride (WNx), tungsten silicide (WSix), titanium, titanium nitride (TiNx), titanium silicide (TiSix), aluminum, aluminum nitride (AlNx), aluminum, cobalt silicide (CoSix), tantalum, tantalum nitride (TaNx), tantalum silicide (TaSix), nickel silicide (NiSix), or a mixture thereof. Each of the gate electrodes may have a single layer structure that includes a polysilicon film pattern, a metal film pattern or a metal compound film pattern. Alternatively, the gate electrodes may have multi layer structures including polysilicon film patterns, metal film patterns and/or metal compound film patterns, respectively.

The gate masks of the gate structures may include materials having etching selectivities relative to the gate electrodes, and gate insulation layers 525, etc. For example, each of the gate masks may be formed using nitride such as silicon nitride or oxynitride like silicon oxynitride.

A third photoresist pattern 560 is formed on the gate insulation layer 525. The third photoresist pattern 560 exposes the gate structures positioned in the peripheral circuit area of the substrate 500 whereas the third photoresist pattern 560 covers the photodiodes 545, the gate structures adjacent to the photodiodes 545 and portions of the gate insulation layer 525 on which a P type MOS transistor and a transfer transistor are formed.

Impurities are doped into portions of the epitaxial layer 505 through the gate insulation layer 525 exposed by the third photoresist pattern 560. Thus, first impurity regions 565 are formed at the portions of the epitaxial layer 505 adjacent to the exposed gate structures. Each of the first impurity regions 565 may have a conductivity type substantially the same as that of the epitaxial layer 505. Further, the first impurity regions 565 may have relatively low impurity concentrations.

Referring to FIG. 10, a fourth photoresist pattern 570 is formed on the gate insulation layer 525 after removing the third photoresist pattern 560 from the gate insulation layer 525. For example, the third photoresist pattern 560 may be removed by an ashing process and/or a stripping process. The fourth photoresist pattern 570 may expose the portion of the gate insulation layer 525 on which the P type MOS transistor is formed.

Impurities are implanted into portions of the epitaxial layer 505 through the portion of the gate insulation layer 525 exposed by the fourth photoresist pattern 570, so that second impurity regions 575 are formed adjacent to the gate structure positioned on the portion of the gate insulation layer 525 where the P type MOS transistor is formed. Each second impurity region 575 may have a conductivity type substantially different from that of the epitaxial layer 505. Additionally, each of the second impurity regions 575 may have a relatively low impurity concentration.

The fourth photoresist pattern 570 is removed from the gate insulation layer 525 after forming the second impurity regions 575. For example, the fourth photoresist pattern 570 may be removed by an ashing process and/or a stripping process.

Referring to FIG. 11, a spacer formation layer (not illustrated) is formed on the gate insulation layer 525 to cover the gate structures. The spacer formation layer may be conformally formed along the profiles of the gate structures. The spacer formation layer may be formed using nitride or oxynitride. For example, the spacer formation layer may include silicon nitride or silicon oxynitride. Further, the spacer formation layer may be formed by a CVD process, a plasma enhanced chemical vapor deposition (PECVD) process, a low pressure chemical vapor deposition process (LPCVD), etc. The spacer formation layer may have a thickness of about 500 Å based on an upper surface of the gate insulation layer 525.

A fifth photoresist pattern 585 is formed on a portion of the spacer formation layer positioned on the gate structures and the gate insulation layer 525 adjacent to the photodiodes 545. Other gate structures are exposed by the fifth photoresist pattern 585. The spacer formation layer is partially etched to form gate spacers 583 on sidewalls of the gate structures exposed by the fifth photoresist pattern 585. For example, the gate spacers 583 may be formed by an anisotropic etching process.

Using the fifth photoresist pattern 585 as implantation masks, impurities are doped into portions of the substrate 500, such that third impurity regions 590 are formed at the first and the second impurity regions 565 and 575 adjacent to the gate structures. Each of the third impurity regions 590 may have a relatively high impurity concentration. Some of the third impurity regions 590 may have conductivities substantially the same as that of the epitaxial layer 505 whereas others of the third impurity regions 590 may have conductivities different from that of the epitaxial layer 505. For example, the third impurity regions 590 positioned at the first impurity regions 565 may have first conductivities whereas the third impurity regions 590 located at the second impurity regions 575 may have second conductivities.

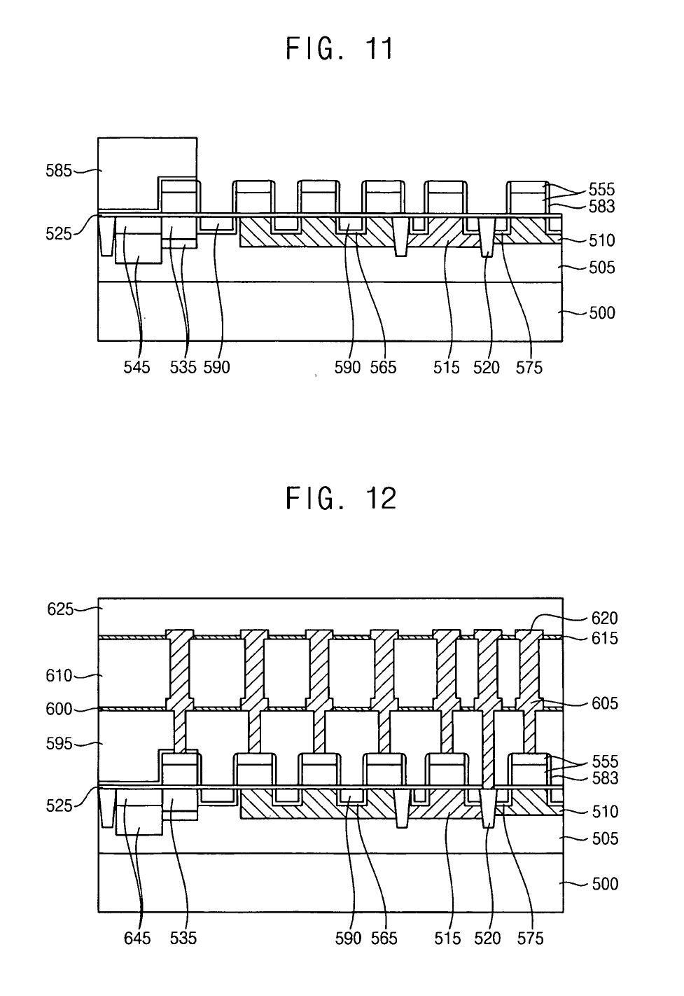

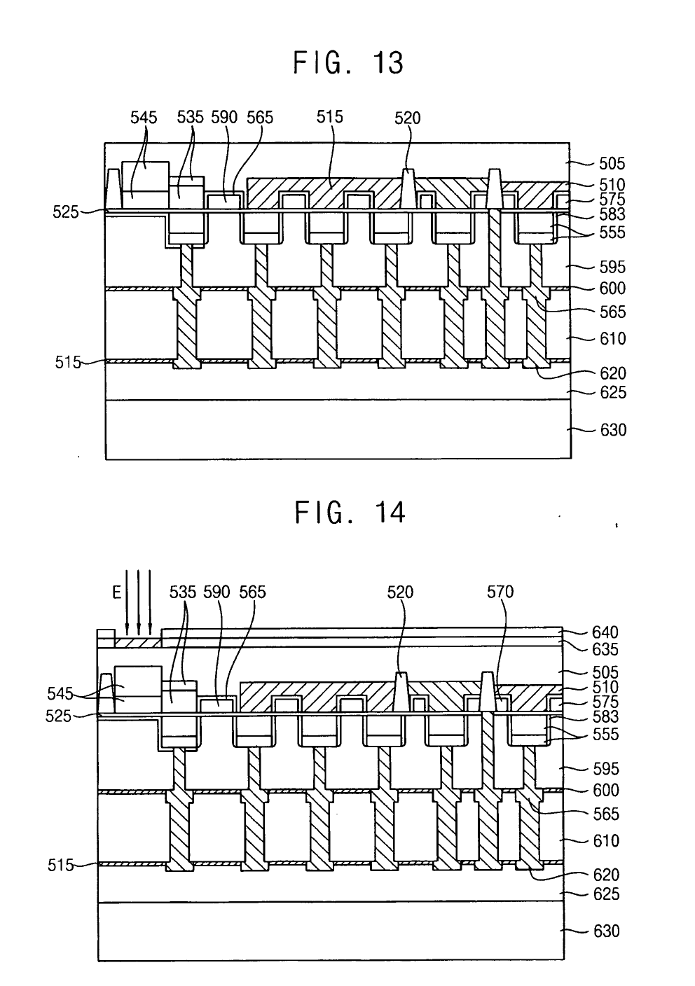

Referring to FIG. 12, a first insulation layer 595 is formed on the gate insulation layer 525 to cover the gate structures having the gate spacers 583 after removing the fifth photoresist pattern 585 from the gate insulation layer 525. The first insulation layer 595 may be formed using oxide. For example, the first insulation layer 595 may include USG, SOG, BPSG, TEOS, PE-TEOS, TOSZ®, FOX, HDP-CVD oxide, or the like. Further, the first insulation layer 595 may be formed by a CVD process, a spin coating process, a PECVD process, an ALD process, an HDP-CVD process, or the like.

In example embodiments, the first insulation layer 595 may have a flat surface by a planarization process. For example, a chemical mechanical polishing (CMP) process and/or an etch-back process may be performed about the first insulation layer 595 to ensure a level surface of the first insulation layer 595.

A first etch stop layer 600 is formed on the first insulation layer 595. The first etch stop layer 600 may be formed using a material having an etching selectivity with respect to the first insulation layer 595. For example, the first etch stop layer 600 may include nitride like silicon nitride or oxynitride such as silicon oxynitride. The first etch stop layer 600 may be formed by a CVD process, a PECVD process, an LPCVD process, an ALD process, or the like.

First contact holes (not illustrated) are formed through the first etch stop layer 600 and the first insulation layer 595 by partially etching the first etch stop layer 600 and the first insulation layer 595. The first contact holes may partially expose the gate structures, respectively.

Plugs 605 are formed on the gate structures to fill the first contact holes. The plugs 605 may include metal and/or metal compound. For example, each of the plugs 605 may be formed using tungsten, tungsten nitride, tungsten silicide, titanium, titanium nitride, titanium silicide, aluminum, aluminum nitride, cobalt silicide, tantalum, tantalum nitride, tantalum silicide, nickel silicide, or the like and may be used individually in as mixture. The plugs 605 may be formed by a sputtering process, a CVD process, an ALD process, an evaporation process, or the like. The plugs 605 may make electrical contact with the gate structures.

A second insulation layer 610 is formed on the first etch stop layer 600. The second insulation layer 610 may also be formed using oxide. For example, the second insulation layer 610 may be formed using USG, SOG, TEOS, PE-TEOS, BPSG, PSG, FOX, TOSZ®, HDP-CVD oxide, or the like. Further, the second insulation layer 610 may be obtained by a CVD process, a PECVD process, an ALD process, an HDP-CVD process, a spin coating process, or the like. In example embodiments, the second insulation layer 610 may be planarized by a planarization process. For example, the second insulation layer 610 may have a surface leveled by a CMP process and/or an etch-back process.

A second etch stop layer 615 is formed on the second insulation layer 610. The second etch stop layer 615 may be formed using a material having an etching selectivity with respect to the second insulation layer 610 and/or the first insulation layer 595. For example, the second etch stop layer 615 may be formed using nitride like silicon nitride or oxynitride such as silicon oxynitride. Further, the second etch stop layer 615 may be formed by a CVD process, a PECVD process, an LPCVD process, an ALD process, or the like.

The second etch stop layer 615 and the second insulation layer 610 are partially etched to form second contact holes (not illustrated) that expose the plugs 605. The second contact holes may be formed by an anisotropic etching process.

Referring now to FIG. 12, conductive wirings 620 are formed on the plugs 605 to fill the second contact holes. Thus, the conductive wirings 620 may be electrically connected with the plugs 605. The conductive wirings 620 may be formed using metal and/or metal compound. For example, each conductive wiring 620 may include tungsten, tungsten nitride, tungsten silicide, titanium, titanium nitride, titanium silicide, aluminum, aluminum nitride, cobalt silicide, tantalum, tantalum nitride, tantalum silicide, nickel silicide or a mixture thereof. Additionally, the conductive wirings 620 may be formed by a sputtering process, a CVD process, an ALD process, an evaporation process, or the like. The conductive wirings 620 may make electrical contact with the gate structures through the plugs 605.

A third insulation layer 625 is formed on the second etch stop layer 615 and the conductive wirings 620. The third insulation layer 625 may also include oxide. For example, the third insulation layer 625 may be formed using USG, SOG, TEOS, PE-TEOS, BPSG, PSG, FOX, TOSZ®, HDP-CVD oxide, or the like. Additionally, the third insulation layer 625 may be formed by a CVD process, a PECVD process, an ALD process, an HDP-CVD process, a spin coating process, or the like. In example embodiments, the third insulation layer 625 may also be planarized by a planarization process such as a CMP process and/or an etch-back process to ensure a flat surface of the third insulation layer 625.

Referring to FIG. 13, an additional substrate 630 is attached on the third insulation layer 625. The additional substrate 630 may serve as a handling wafer for forming the image sensor. The additional substrate 630 may include a semiconductor substrate. The substrate 500 is turned over after forming the additional substrate 630 on the third insulation layer 625, so that the rear surface of the substrate 500 is exposed.

The rear portion of the substrate 500 is partially removed until the epitaxial layer 505 is exposed. The substrate 500 may be partially removed by a thinning process. Since the epitaxial layer 505 covers the resultant structures formed on the substrate 500, the resultant structures such as photodiodes 545, impurity regions 565, 575 and 590, the wells 505 and 510 may not exposed after partially removing the rear portion of the substrate 505.

Referring to FIG. 14, an anti-reflective layer 635 is formed on the exposed epitaxial layer 505. The anti-reflective layer 635 may be formed using silicon compound and/or metal compound. For example, the anti-reflective layer 635 may include silicon nitride, silicon oxynitride, titanium oxide (TiOx), tantalum oxide (TaOx), hafnium oxide, zirconium oxide, or a mixture thereof. Further, the anti-reflective layer 635 may be formed by a CVD process, an ALD process, a PECVD process, a sputtering process, an evaporation process, etc. In example embodiments, the anti-reflective layer 635 may have a thickness of about 10 Å to about 1,000 Å based on a surface of the epitaxial layer 505.

A laser mask 640 is formed on the anti-reflective layer 635. The laser mask 640 exposes the light receiving region of the image sensor. The laser mask 640 may be formed using dielectric material, metal and/or metal compound having a relatively high reflectivity. For example, the laser mask 640 may include titanium oxide, zirconium oxide, silicon oxide, hafnium oxide, calcium fluoride (CaFx), magnesium fluoride (MgFx), aluminum oxide (AlOx), zinc sulfide (ZnSx), or a mixture thereof.

Using the laser mask 640, a laser beam (E) is selectively irradiated on a portion of the epitaxial layer 505 corresponding to the light receiving region of the image sensor through the anti-reflective layer 635.

In example embodiments, the laser beam (E) may be irradiated on the epitaxial layer 505 through the anti-reflective layer 635, so that the epitaxial layer 505 may be momentary heated to a relatively high temperature of about 500° C. to about 1,000° C. Namely, a laser annealing process may be performed about the epitaxial layer 505. Therefore, defects such as dangling bonds in the epitaxial layer 505 may be effectively removed. That is, the dangling bonds of silicon and/or silicon and oxygen may be cured by irradiating the laser beam (E) on the epitaxial layer 505. The laser beam (E) may have a wavelength of about 10.0 μm to about 11.0 μm. For example, the laser beam (E) may include a carbon dioxide (CO₂) laser having a wavelength of about 10.6 μm. Further, other suitable laser beams may be used to cure these detects in the epitaxial layer 505 by thermally treating the epitaxial layer 505. The laser beam (E) may have a wavelength ensuring energy substantially smaller than the band gap energy of silicon to effectively cure the dangling bonds in the epitaxial layer 505. Thus, the laser beam (E) may have a wavelength above about 1.2 μm. For example, the wavelength of the laser beam (E) may be substantially larger than about 5.0 μm.

When the laser beam (E) is irradiated on the epitaxial layer 505, the defects in the epitaxial layer 505 may be removed without melting the surface of the epitaxial layer 505. Further, the anti-reflective layer 635 may also have an improved refraction index because the laser beam (E) may heat the anti-reflective layer 635 while curing the dangling bonds in the epitaxial layer 505. That is, the anti-reflective layer 635 may have a dense structure by irradiating the laser beam (E) on the anti-reflective layer 635. A first portion of the anti-reflective layer 635 heated by the laser beam (E) may have a crystalline structure different from that of a second portion of the anti-reflective layer 635 where the laser beam (E) is not irradiated. The first portion of the anti-reflective layer 635 may have minute and dense grains, and the first portion of the anti-reflective layer 635 may have a refraction index substantially the same as that of the epitaxial layer 505. Thus, a difference of refraction index between the anti-reflective layer 635 and the epitaxial layer 505 may be desirably reduced. As a result, the image sensor may ensure an enhanced light transmittance by reducing the reflection of the light incident at an interface between the anti-reflective layer 635 and the epitaxial layer 505.

In example embodiments, various processes may be employed to cure the defects of the epitaxial layer 505 and to improve the refraction index of the anti-reflective layer 635. For example, the defects of the epitaxial layer 505 may be cured and the refraction index of the anti-reflective layer 635 may be enhanced by a flash lamp annealing process, an ultraviolet ray annealing process, or the like. In the flash lamp annealing process or the ultraviolet ray annealing process, the surface of the epitaxial layer 505 and the anti-reflective layer 635 may be uniformly thermally treated such that the image sensor may have improved characteristics.

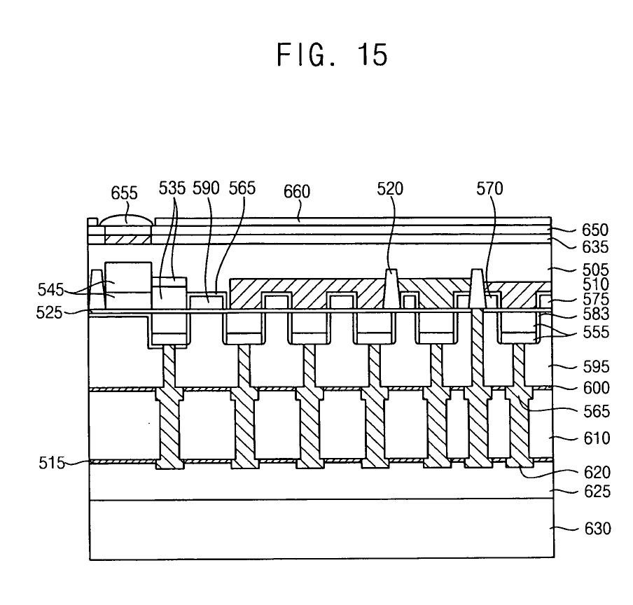

Referring to FIG. 15, the anti-reflective layer 635 is planarized after removing the laser mask 640 from the anti-reflective layer 635. The anti-reflective layer 635 may have a surface leveled by a CMP process and/or an etch-back process.

A color filter layer 650 is formed on the anti-reflective layer 635 having a flat surface. Although one photodiode 545 is illustrated in FIG. 15, at least three photodiodes 545 may include one color pixel when a color filter array (CFA) including a red color filter layer, a blue color filter and a green color filter is formed on the anti-reflective layer 635.

A micro lens 655 is disposed on the color filter layer 650. Light may pass through the micro lens 655 and then the color filter 650 may selectively collect a desired color light. The selected color light may be converted as charges by the photodiode 545 through photoelectric transformation mechanism.

According to example embodiments, the epitaxial layer 505 and the anti-reflective layer 635 may be thermally treated, so that the defects in the epitaxial layer 505 may be cured and the refraction index of the anti-reflective layer 635 may be improved. Therefore, the image sensor including the epitaxial layer 505 and the anti-reflective layer 635 may ensure enhanced characteristics.

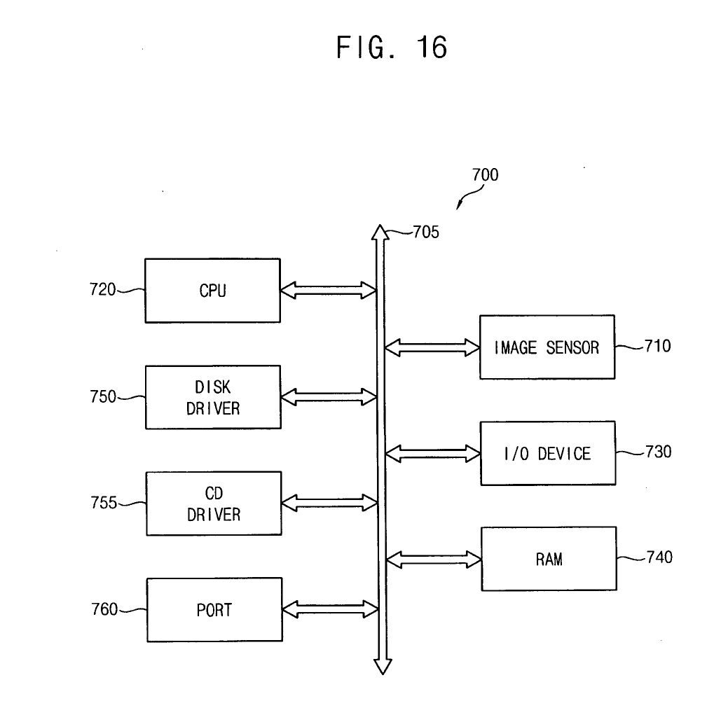

FIG. 16 is a block diagram illustrating an electronic system including an image sensor according to example embodiments.

Referring to FIG. 16, an electronic system 700 including an image sensor 710 may process and may produce pictures generated from the image sensor 710. The image sensor 710 may have a construction somewhat similar to the image sensor according to example embodiments disclosed above. The electronic system 700 may include a computer system, a camera system, an image communication cellular phone, a scanner, an image stabilizing system and/or other electronic systems that may utilize the image sensor.

When the electronic system 700 is a processing system such as the computer system, the electronic system 700 includes a central processing unit (CPU) 720 such as a micro processer. The CPU 720 may communicate with an input/output (I/O) device 730 through a bus 705. The disk driver 750, a compact disc (CD) driver 755, a port 760 and/or a random access memory (RAM) 740 may be electrically connected to the CPU 720, and signals may be transferred among the disk driver 750, the CD driver 755, the port 760, the RAM 740 and CPU 720. Therefore, desired pictures may be produced based on the data generated by the image sensor 710.

The port 760 may connect to a video card, a sound card, a memory card, a universal serial bus (USB), or the like. Alternatively, the port 760 may include an additional port for transmitting/receiving data with other communication systems.

In example embodiments, the image sensor 710 may be integrated on a substrate together with the CPU 720, a digital signal processing (DSP) device, a micro processer, etc. Further, the image sensor 710 and a memory device may be integrated on one substrate. Alternatively, the image sensor 710 may be separate from the CPU 720, a digital signal processing (DSP) device, a micro processer, and/or memory device.

When the electronic system 700 includes the image sensor 710 in which defects such as dangling bonds are cured, the electronic system 700 may produce enhanced pictures having improved qualities.

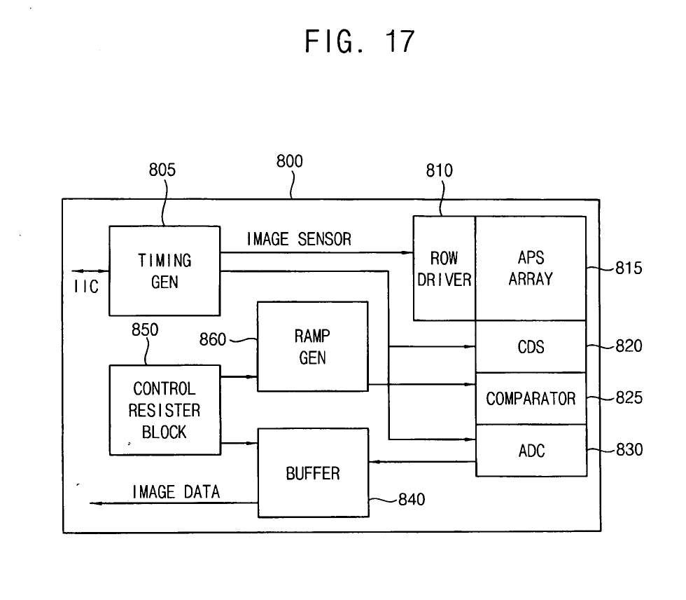

FIG. 17 is a block diagram representation of an image sensor chip included in an electronic system according to example embodiments.

Referring to FIG. 17, an image sensor 800 as an individual chip includes a timing generator 805, an APS array 815, a correlated double sampling (CDS) 820, a comparator 825, an analog to digital convertor (ADC) 830, a buffer 840, and/or a control register block 850. Here, the image sensor 800 may have a construction somewhat similar to the image sensor according to example embodiments disclosed above.

The APS array 815 may include an optical lens for collecting optical data of an object. The optical data may be converted and amplified into voltages through electron conversion and voltage conversion mechanisms. The CDS 820 may remove noise from the amplified voltage, and then may select requested signals. The comparator 825 may compare the selected signals, and may synchronize the compared signals. The ADC 830 may convert the synchronized analog signals into digital data image signals. These digital image signals may pass the buffer 840, and then the electronic system having the image sensor 800 may produce the image of the object. Since the system includes the image sensor 800 having enhanced characteristics without generating dark current therein, the system may improve the quality of the image of the object.

According to example embodiments, defects including dangling bonds on a substrate may be cured and an anti-reflective layer may be made dense by a thermal treatment process, so that an image sensor including the substrate and the anti-reflective layer may have an improved light transmittance and may produce high-definition images.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A method of manufacturing an image sensor, comprising:
forming a photodiode on a light receiving region of a substrate having a first surface;
forming a conductive wiring on the first surface of the substrate;
removing a portion of the substrate opposite to the first surface;
forming an anti-reflective layer on a second surface of the substrate, the second surface being opposite to the first surface; and
thermally treating the anti-reflective layer and the light receiving region of the substrate.

2. The method of claim 1, wherein thermally treating the anti-reflective layer and the light receiving region of the substrate includes a laser annealing process, a flash lamp annealing process or an ultraviolet ray annealing process.

3. The method of claim 1, wherein thermally treating the anti-reflective layer and the light receiving region of the substrate cures defects in the light receiving region and increases a refraction index of the anti-reflective layer.

4. The method of claim 3, wherein thermally treating the anti-reflective layer and the light receiving region of the substrate is performed using a laser beam having an energy smaller than a band gap energy of silicon.

5. The method of claim 4, wherein the laser beam has a wavelength greater than about 1.2 μm.

6. The method of claim 1, wherein thermally treating the anti-reflective layer and the light receiving region of the substrate is performed at a temperature of about 500° C. to about 1,000° C.

7. The method of claim 1, wherein the anti-reflective layer includes a silicon compound or a metal compound.

8. The method of claim 7, wherein the anti-reflective layer includes silicon nitride, silicon oxynitride, titanium oxide, tantalum oxide, hafnium oxide, zirconium oxide or a combination thereof.

9. The method of claim 1, wherein the anti-reflective layer has a refraction index of about 1.5 to about 3.0.

10. The method of claim 1, further comprising:
decreasing a difference in refraction index between the anti-reflective layer and the substrate by thermally treating the anti-reflective layer and the light receiving region of the substrate.

11. The method of claim 1, further comprising:
forming an epitaxial layer on the substrate before forming the photodiode, and removing the portion of the substrate till the epitaxial layer is exposed.

12. The method of claim 11, wherein forming the photodiode comprises:
doping first impurities in a portion of the epitaxial layer and doping second impurities on the first impurities.

13. The method of claim 1, further comprising:
forming at least one gate structure on the first surface of the substrate;
forming at least one insulation layer covering the at least one gate structure; and
electrically connecting the conductive wiring to the at least one gate structure through the at least one insulation layer.

14. The method of claim 1, further comprising:
forming a color filter layer on the anti-reflective layer; and
forming a micro lens on the color filter layer.

15.-20. (canceled)
